(19) United States
(12) Patent Application Publication
(10) Pub. No.: US 2017/0275155 A1
(43) Pub. Date: Sep. 28, 2017

(54) A CHEMICAL BIOCHEMICAL OR BILOGICAL ANALYSIS SYSTEM UTILIZING LUMINESCENT DETECTION

(71) Applicant: RMIT University, Victoria (AU)

(72) Inventors: Ana Maria GRACIOSO MARTINS, Victoria (AU); Sally HARRISON, Victoria (AU); Amgad R. REZK, Victoria (AU); Nichola Anne PORTER, Victoria (AU); Peter David CARPENTER, Victoria (AU); Johan DU PLESSIS, Victoria (AU); James R. FRIEND, San Diego, CA (US); Leslie Y. YEO, Victoria (AU)

(21) Appl. No.: 15/505,786

(22) PCT Filed: Aug. 20, 2015
(86) PCT No.: PCT/AU2015/050479

§ 371 Date: Feb. 22, 2017

(30) Foreign Application Priority Data
Aug. 22, 2014 (AU) 2014903317
May 22, 2015 (AU) 2015901888

(51) Int. Cl. B81B 7/02; B06B 1/06; G01N 21/62

(52) U.S. Cl. CPC B81B 7/02; G01N 21/62; B06B 1/06; G01H 9/00

(57) ABSTRACT

A chemical, biochemical or biological analysis system and method including: a surface acoustic wave (SAW) actuator (6) including a piezoelectric substrate (9) and at least one interdigital electrode (17) located on a working surface (11) of the piezoelectric substrate (9), the SAW actuator generating travelling SAWs in the working surface when an electrical signal is applied to the interdigital electrode; at least one reaction chamber (19) located on the working surface of the piezoelectric substrate; a light detector (16) for detecting luminescent, fluorescent or phosphorescent emissions within the reaction chamber; a reagent flow line (29) for providing a flow of reagent through the reaction chamber; a test sample supply line (29) for supplying a test sample to the reaction chamber; wherein the SAW actuator can generate travelling SAWs within the working surface to thereby induce chaotic micromixing, convective transport, concentration or combinations thereof of the test sample and the reagent contained within the reaction chamber.

### FIELD OF THE INVENTION

The present invention is generally directed to chemical, biochemical and biological analysis systems for detecting luminescence in mixed test sample and reagent solutions. While the present invention will be described in relation to flow injection analysis (FIA) systems, it is to be appreciated that the present invention is not limited to such systems, and the use of the present invention in other chemical, biochemical and biological analysis systems is also envisaged. Examples of other chemical, biochemical and biological analyses include the detection of fluorescent, luminescent (including but not limited to chemiluminescent, electrochemiluminescent and bioluminescent) or phosphorescent species, including but not limited to liquids, solutes, molecules or particulate matter in solution or adhered to other soluble structures such as bead-based assays, antibodies, aptamers, or other suitable chemical or biochemical functional groups.

### BACKGROUND TO THE INVENTION

Chemiluminescence is a powerful resource in quantitative chemical analyses as it permits the sensitive and specific detection of certain functional groups in target analytes. The light emitted by chemiluminescent species can be captured and amplified by a photo detector, in this case a photomultiplier tube, and correlated to the concentration of target analyte. Likewise, the light emitted by fluorescent, luminescent or phosphorescent molecules can also be captured in the same manner.

However, due to the short-lived nature of the chemiluminescent emissions (10⁻¹⁵ s), accurate chemical quantification is only possible when the chemiluminescent reaction takes place directly in front of the photomultiplier tube. Conventional chemiluminescent detection systems are designed to capture chemiluminescent emissions as they are generated through passive mixing inside a mixing coil. The reliance on passive mixing, however, limits the sensitivity and accuracy of the system as the chemiluminescent reaction yields are lower in such systems. Fluorescent and phosphorescent emissions have relatively longer half-lives when compared to chemiluminescent emissions. However, because these species are often present at very low concentrations in biological assays and typically rely on diffusion for the transport of the species to be detected from the bulk of the sample to the detection surface, their fast and accurate detection at greater sensitivity levels (or lower limits of detection) would greatly benefit from convective micromixing to overcome diffusion transport limitations and/or species concentration of the species to yield a greater aggregated signal in front of the photodetector.

Conventional chemiluminescent detection systems are also relatively large in size and weight limiting their portability. Furthermore, these conventional systems typically require a mains power supply to operate. Fluorescent, luminescent and phosphorescent detection systems usually require benchtop excitation sources and emission filters for benchscale batch analysis.

It is therefore an object of the present invention to provide a chemical analysis system and method using chemiluminescent detection that addresses one or more of the above noted disadvantages of conventional chemiluminescent detection systems. Similarly, the object of the present invention is also to provide a chemical, biochemical or biological analysis system and method using luminescent, fluorescent or phosphorescent detection that addresses one or more of the above noted disadvantages of conventional detection systems using these methods.

### SUMMARY OF THE INVENTION

According to one aspect of the present invention, there is provided a chemical, biochemical or biological analysis system including:
a surface acoustic wave (SAW) actuator including a piezoelectric substrate and at least one interdigital electrode located on a working surface of the piezoelectric substrate, the SAW actuator generating travelling SAWs in the working surface when an electrical signal is applied to the interdigital electrode;
at least one reaction chamber located on the working surface of the piezoelectric substrate;
a light detector for detecting luminescent, fluorescent or phosphorescent emissions within the reaction chamber;
a reagent flow line for providing a flow of reagent through the reaction chamber;
a test sample supply line for supplying a test sample to the reaction chamber;
wherein the SAW actuator can generate travelling SAWs within the working surface to thereby induce chaotic micromixing, convective transport, concentration or combinations thereof of the test sample and the reagent contained within the reaction chamber.

The luminescent emissions may include chemiluminescent, electrochemiluminescent or bioluminescent emissions. The system according to the present invention can not only detect chemical or biochemical species (analytes, DNA, RNA, proteins or peptides), but also biological species (e.g., cells). The SAW, in addition to including micromixing, can also induce fast convective transport (to overcome slow diffusion of the species within the reaction chamber) and also concentration of species to yield an aggregated (and hence more intense) luminescent, fluorescent or phosphorescent missions.

The Applicant's International Publication No. WO2007/1280046 describes the influence of SAWs in driving micromixing within a small liquid volume. Furthermore, the Applicant has determined that travelling surface acoustic waves that travel along the working surface, as distinct from standing surface acoustic waves that remain stationary on the working surface, facilitates micromixing. This is as a result of the leakage of SAW energy from the travelling SAW generated in the working surface into the liquid within the reaction chamber. This leads to strong liquid recirculation as a result of acoustic streaming within the liquid induced by the SAW. This then results in chaotic convection within the reaction chamber. Therefore, any laminarity of the liquid flow within the reaction chamber is disrupted thereby enhancing mixing within the reaction chamber. Standing SAW does not induce the same chaotic mixing within a liquid volume exposed to such SAW. The reaction chamber may preferably have a substantially circular cross-section as this further enhances the micromixing therein. The provision of a reaction chamber preferably having a substantially circular cross-section together with the use of travelling SAW to induce micromixing of the test sample and analyte within that reaction chamber leads to significantly improved mixing over systems utilising passive mixing. Therefore, induced chaotic mixing can occur within the reaction chamber as a result of the travelling SAW generated within the working surface and the energy transferred from the SAW into the liquid contained within the reaction chamber. The reaction chamber provides a sufficient volume to allow for such mixing to occur. By the same token, the emission yield from fluorescent, luminescent or phosphorescent matter or tags on bead-based assays can also benefit from micromixing that enhances convective transport to overcome diffusion transport limitations of the analyte to be detected and the concentration of the fluorescent, luminescent or phosphorescent matter or tags on bead-based assays to provide a stronger aggregated signal.

The light detector may be a photomultiplier tube having a photodetector cell for detecting the chemiluminescent emissions within the reaction chamber. The diameter of the reaction chamber may preferably be sized to substantially match the diameter of the photodetector cell, with the photodetector cell be placed against a rear side of the piezoelectric substrate and aligned with the reaction chamber. This configuration promotes enhanced chemiluminescent yields and optimal light detection which translates into more sensitive and accurate quantification. Similarly, a photomultiplier tube or any other sensitive photodetector can be used to detect fluorescent, luminescent or phosphorescent emissions through an emission filter placed directly underneath the piezoelectric substrate. In this configuration, an excitation source is placed directly above the reaction chamber in order to excite the fluorescent, luminescent or phosphorescent species and an emission filter is placed between the piezoelectric substrate and the photodetector.

The chemical analysis system may preferably be a flow injection analysis (FIA) system wherein the reagent flow line includes a reagent injector for injecting a continuous flow of the reagent to the reaction chamber, and the test sample flow line includes a sample injector for injecting a batch of the test sample into the reaction chamber. The construction of the present invention allows for an FIA system that is significantly smaller in size and having greater portability than known FIA systems. Furthermore, the use of SAW actuators also allow for such a system to be battery powered further improving its portability.

The reaction chamber may include a reagent inlet port in communication with the reagent flow line. The reaction chamber may further include a sample inlet port in communication with the sample flow line. The reaction chamber may also include an outlet port for the fluid contained within the reaction chamber. The inlet ports and outlet port may be positioned relative to each other such that a line passing through the outlet port and between the inlet ports may be substantially aligned perpendicular to a general propagation direction of the SAW within the working surface. This can increase the residence time of the liquid within the reaction chamber leading to improved mixing or concentration efficiency. The mixing efficiency may also be improved by positioning the inlet ports and outlet ports may be located relative to each other such that a line passing through the outlet port and between the inlet ports may be substantially aligned with a general propagation direction of the SAW within the working surface, with the outlet port being located closest to the source of the SAW. It has been found that this can maximise the degree of mixing that can be achieved within the reaction chamber by further increasing the residence time therein.

The SAW actuator may be subjected to a pulsed said electrical signal where the signal is turned on and off rapidly. This can lead to improved mixing or concentration efficiency within the reaction chamber. Furthermore, this can reduce the power consumption of the system facilitating miniaturization of the system.

The system may preferably include two said interdigital electrodes located on opposing sides of the reaction chamber. This arrangement then allows SAW to be generated from either side of the reaction chamber increasing the energy that can be transferred to the fluid within the reaction chamber. Furthermore, the use of a pair of interdigital electrodes facilitates the generation of travelling SAW.

According to another aspect of the present invention, there is provided a chemical, biochemical and biological analysis method utilising luminescent detection in a chemical, biochemical and biological analysis system as described above, the method including:
applying an electrical signal to the SAW actuator to generate travelling SAW in the working surface of the piezoelectric substrate;
providing a flow of reagent through the reaction chamber;
supplying a test sample to the reaction chamber,
the generated travelling SAW inducing chaotic micromixing, convective transport,
concentration or combinations thereof of the test sample and the reagent within the reaction chamber; and
detecting luminescent emissions from the mixed test sample and reagent.

The method may include providing a continuous flow of reagent to the reaction chamber, and providing a batch of the sample to the reaction chamber. Furthermore, the method may include applying a pulsed electrical signal to the SAW actuator.

The Applicants have been found that the SAW induces strong and chaotic acoustic streaming within the liquid contained within the reaction chamber which disrupts the laminarity of the flow therein. Furthermore, as the mixing occurs within the reaction chamber, the chemiluminescent emissions will occur within the reaction chamber and can be captured by the chemiluminescent detector. The Applicants have found that the system according to the present invention has significantly higher sensitivity to chemiluminescent emissions than known systems. In experiments conducted by the Applicant, a theoretical limit of detection of 0.2 ppb (0.2 nM) of L-Proline were achieved by the chemical analysis system according to the present invention. This is a decade improvement over the industry gold-standard and two orders of magnitude more sensitive than that achievable with conventional systems. The high sensitivity of the system allows for the detection of any chemiluminescent species in the liquid phase without the need for sample preconcentration. Likewise, the Applicants have also found that the SAW induces rapid concentration of species that include but are not limited to molecules and beads into a tight aggregate such that their collective light signal is significantly greater than that emitted by individual species on their own, thus enhancing the detection species by at least a million times. In addition, the chemical, biochemical and biological analysis system according to the present invention can be readily miniaturized because of its use of SAW actuation which can be powered using a battery power supply. This enables the system to be portable thereby allowing applications of the system in for example the detection of pesticides in water supplies.

### BRIEF DESCRIPTION OF THE DRAWINGS

It will be convenient to further describe the invention with respect to the accompanying drawings which illustrate a preferred embodiment of the chemical analysis system of the present invention. Other embodiments of the invention are possible, and consequently, the particularity of the accompanying drawings is to be understood as superseding the generality of the preceding description of the invention.

In the drawings:

FIG. 1 is an image of a prototype chemical analysis system according to the present invention;

FIG. 2 is a schematic perspective view of the SAW actuator and reaction chamber of the chemical analysis system of FIG. 1;

FIG. 3 is a graph showing the effect of the SAW surface displacement on a steady state normalised mixing index showing images of the mixing within the reaction chamber;

FIG. 4 is a graph showing the normalised average pixal density for images of the reaction chamber at steady state as a function of the SAW amplitude and modulation;

FIG. 5 is a graph showing the steady state normalise mixing index as a function of the volumetric flow rate through the reaction chamber and hence the liquid residence time in the chamber for difference SAW surface displacement amplitudes, both in continuous and pulsed modes;

FIG. 6 is a graph showing the steady state normalise mixing index for different chamber orientations;

FIG. 7 is a graph showing the detection of proline using the PMT integrated into the continuous flow microfluidic device in the presence of SAW micromixing.

FIG. 8 is a schematic perspective view of the prototype chemical analysis system adapted for fluorescent, luminescent or phosphorescent analysis featuring an excitation source, an excitation filter (facultative) and an emission filter.

### DETAILED DESCRIPTION OF THE INVENTION

Flow injection analysis (FIA) is a versatile analytical technique widely used for the analysis of chemical species in liquid phase wherein species are quantified as a function of the signal produced by a detectable change in physical property (pH, conductivity, electrode potential, wavelength, light absorption or emission) at any given point of a reaction coordinate in a dynamic flow system. This flexibility makes FIA a powerful method for liquid phase chemical quantification, especially for the analysis of environmental, food and biological samples. Nevertheless, the requirement of laboratory benchscale equipment for sample preparation (usually a multistep procedure) and injection, reaction as well as detection in conventional FIA typically prohibit miniaturisation of these systems to exploit the advantages of low reagent consumption and short analysis times, as well as portable field use, which is desirable for applications such as water quality monitoring and on-site water testing of pollutants. Even when portability is claimed, the reported FIA systems are still relatively large, cumbersome and heavy. Moreover, the sub-ppb detection sensitivity necessary for water monitoring and testing often necessitates additional equipment for sample preconcentration in these systems, which further limits options for their portability.

The present invention provides a microfluidic FIA platform that addresses this limitation. Advances in detection technology have since significantly improved detector sensitivity, which, together with optimised reaction kinetics, has facilitated the quantification of a range of previously undetectable compounds. For example, the use of photochemical oxidative processes, derivatisation, immunoassays, fluorescent labels, and even the immobilisation of reactants or substrates onto newly designed materials has vastly extended the repertoire of FIA as a flexible and sensitive micro-analytical technique. For example, FIA-Chemiluminescence (FIA-CL) and FIA-Fluorescence (FIA-FL) offer the possibility for limits of quantification that are comparable to those of other sensitive conventional analytical techniques such as CE, LC-MS and GC-MS. Further, chemiluminescent reagents display a high degree of selectivity in their reaction with chemiluminogenic compounds, emitting distinct light wavelengths that can be captured with highly sensitive detectors such as photomultiplier tubes (PMTs), charge coupled devices (CCDs) or complementary metal-oxide semiconductor (CMOS) cameras, whose advances have enabled miniaturisation into portable handheld systems.

Nevertheless, the ability to completely miniaturise the FIA detection platform cannot be achieved merely by incorporating these portable sensors, especially given the compromise in detection sensitivity with scale down in size. As such, the kinetics of the reaction must be taken into account in the design of these systems in addition to favourable stereochemical conditions. Given the fast chemiluminescent reaction timescales, the process is typically diffusion-limited due to the absence of turbulent mixing vortices in the typical low Reynolds number laminar flow conditions of a FIA system, and thus micromixing is an important consideration not only to increase reaction yield (in this case, the intensity of the chemiluminescent signal) and hence allow lower limits of detection with a given sensor, but also to attain sufficiently short residence times that, in turn, facilitate scale down in the dimensions of the reaction chamber. In view of their relative simplicity, passive sample-reagent mixing strategies such as the incorporation of serpentine channels and flow obstructions, for example, have therefore been adopted in many FIA-CL platforms to increase the rate of reaction despite their lower mixing efficiencies, longer residence times, larger associated pressure drops and fabrication complexities compared to their active counterparts. This has primarily been due to the lack of a low cost and efficient active micromixing scheme that can be easily integrated to date, especially if portability is desired.

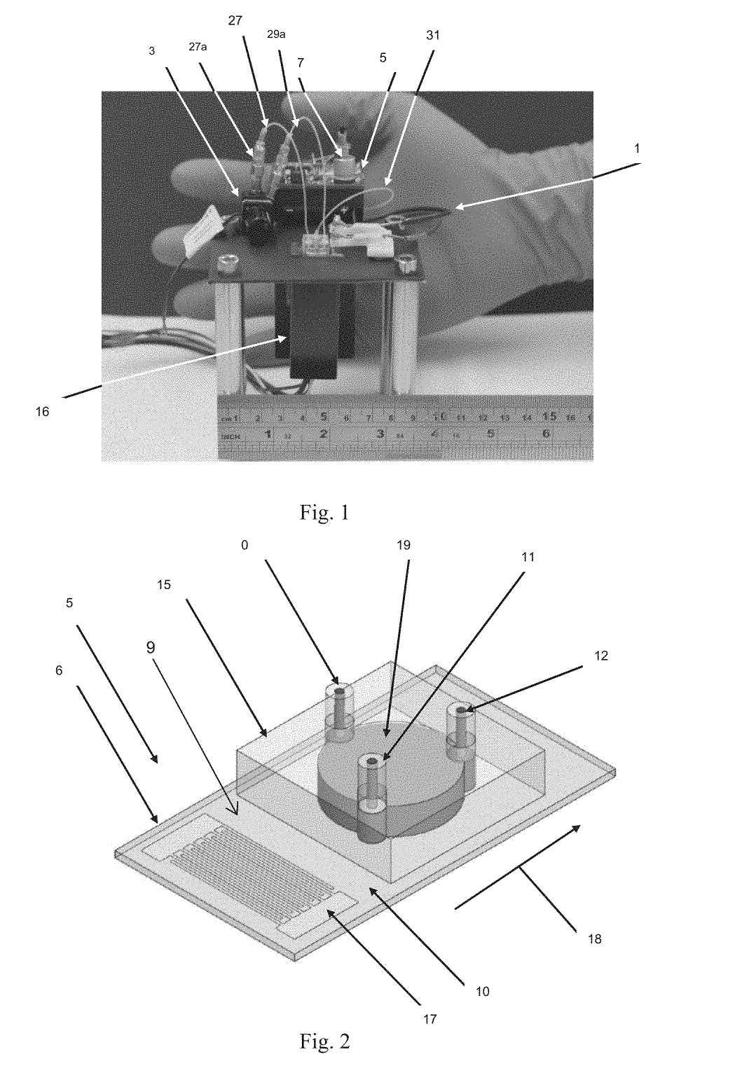

The Applicants have demonstrated that the use of acoustics to drive active micromixing of chemiluminogenic compounds is able to enhance the mixing efficiency to a sufficient extent that limits of detection superior to that using conventional benchscale FIA instrumentation and within the desired order of magnitude of chemiluminescent micro-analyses can be achieved with a portable PMT integrated into a microfluidic chamber. More specifically, the Applicant exploit the use of surface acoustic waves (SAWs)—nanometre amplitude high frequency (MHz order) electromechanical waves that propagate on the surface of a piezoelectric substrate—which has recently been shown not just as a powerful tool for microscale fluid manipulation (as described in the Applicant's International Publication No. WO2007/128046) but also one that can efficiently be driven using a battery-powered portable handheld circuit. Whilst batch chaotic micromixing via SAW-generated acoustic streaming has been demonstrated in a sessile drop, microchamber, microchannel, microdisc and in paper, the present invention presents the first instance of a preferably continuous flow micromixing strategy in addition to complete on-chip integration with a portable photodetection scheme. Together with the ability to incorporate integrated chip-scale SAW continuous flow micropumps, this on-chip microfluidic mixing strategy and integrated miniature photodetector therefore constitutes a completely miniaturised platform for portable field-use miniaturised FIA systems (FIG. 1) that is able to achieve current industry standard limits of detection without the need for sample preconcentration.

FIG. 1 shows an image of the prototype portable FIA system 1 which includes a micropump 3, the SAW device 5 including a SAW actuator 6 having a piezoelectric substrate 9 with a working surface 10 and one or more interdigital electrodes 17 located on the working surface 11. The SAW actuator 6 generates travelling SAW within the working surface 11. FIG. 2 shows in more detail the SAW device 5 used in the system 1. The SAW device 5 is powered by a miniature drive circuit 7 that includes a signal generator and amplifier. A PDMS reaction chamber housing 15 is bonded to the working surface 10 of the SAW actuator 6, the housing 15 including a reaction chamber 19 having a circular cross-section located within the housing 15. The reaction chamber housing 15 is also provided with a reagent inlet port 11, a test sample inlet port 12, and an outlet port 0. The system 1 further includes a reagent fluid line 27 having a reagent injector 27A for injecting reagent into the reaction chamber 19 through the reagent inlet point 21, and a test sample fluid line 29 having a test sample injector 29A for injecting a batch of the test sample through the test sample inlet port 23 into the reaction chamber 19. An outlet fluid line 31 is connected to the outlet port 0 to allow removal of the fluid from the reaction chamber 19. A portable photodetector 16 is provided under the reaction chamber 19 for detecting chemiluminescent emissions within the reaction chamber 19. The prototype system 1 as shown in FIG. 1 shows the possibility for complete integration and portability for field use. The total weight of the entire prototype system is approximately 130 g.

The following description provides details of the fabrication process of the SAW device 5, the methods used to conduct experiments on the SAW device 5, and the results obtained from those experiments.

### Materials and Methods

### Materials

Tris(2,2′-bipyridyl)dichlororuthenium(II) hexahydrate ([Ru(bipy)₃]²⁺) is a chemiluminescent reagent that has been widely described in the literature and utilised for the analysis of various classes of compounds such as amines, amino acids, organic acids, illicit drugs, pharmaceuticals, and pesticides. Due to its wide applicability, [Ru(bipy)₃]²⁺ is thus the reagent of choice in this study, whose chemiluminescent reaction can be summarised by

Ru(bipy)₃²⁺(oxidation) Ru(bipy)₃³⁺,

Ru(bipy)₃³⁺+Analyte(reduction) [Ru(bipy)₃²⁺]*, and

[Ru(bipy)₃²⁺]*Ru(bipy)₃²⁺+[Ru³⁺(buoy)⁻(bipy)₂]²⁺+h .

In general, the [Ru(bipy)₃]²⁺ species is oxidised by a catalyst into its chemiluminogenic form tris(2,2′-bipyridyl)dichlororuthenium(III) hexahydrate ([Ru(bipy)₃]³⁺). The reaction of [Ru(bipy)₃]³⁺ with an electron-rich analyte then gives rise to the excited-state [Ru(bipy)₃²⁺]*, which subsequently relaxes back to its ground-state [Ru(bipy)₃]²⁺ by emitting light in the form of photon energy h while also forming the byproduct [Ru³⁺(bipy)⁻(bipy)₂]²⁺. The amount of light emitted by the chemiluminescent reaction is, fundamentally, a function of the analyte concentration under optimised reaction conditions as it is the direct result of the reduction of [Ru(bipy)₃]³⁺ to [Ru(bipy)₃]²⁺ and [Ru³⁺(bipy)⁻(bipy)₂]²⁺ by the analyte.

Proline—a uniquely structured-amino-acid featuring a secondary amine group which readily reacts with [Ru(bipy)₃]³⁺—is employed as our analyte of choice given that it is widely used in similar chemiluminescent detection studies and since numerous micro-analytical chemiluminescence methods have been developed to target it for the determination of nitrogen content in amino-acid-rich matter such as foods, animal tissues and other forms of organic matter, other chemiluminescent reagents with similar applications are luminol, diaryloxalates and potassium permanganate. Specifically, L-proline (analytical grade; Sigma-Aldrich Pty Ltd., Castle Hill, NSW, Australia) standards were prepared in 50.0 mM sodium tetraborate buffer (analytical grade, Ajax Finechem; Thermo Fisher Scientific Pty. Ltd., North Ryde, NSW, Australia) and adjusted to pH 9.0 using hydrochloric acid (analytical grade, Ajax Finechem; Thermo Fisher Scientific Pty. Ltd., North Ryde, NSW, Australia). 1.0 mM [Ru(bipy)₃]²⁺ (analytical grade, Sigma-Aldrich Pty. Ltd., Castle Hill, NSW, Australia) was prepared in 200.0 mM sulphuric acid and oxidised to [Ru(bipy)₃]³⁺ using 1.0 g of lead dioxide powder (analytical grade, Merck Pty. Ltd., Kilsyth, VIC, Australia) and filtered in-line using a 0.45 m teflon microfilter (Labquip Ltd., Dublin, Ireland).

### Device Fabrication

The SAW device 5 was designed with a simple unweighted interdigital electrode described elsewhere with 20 electrode finger pairs to operate at 19.6 and 21.5 MHz on single crystal lithium niobate in a 127.68° Y-rotated, X-propagating cut (Roditi International Corp., London, UK), fabricated using lift-off photolithography. Briefly, double side polished lithium niobate wafers were piranha-cleaned (3:1 H₂SO₄:H₂O₂) for 20 mins. The wafers were then rinsed with water and isopropanol and subsequently dried with nitrogen. AZ4562 photoresist (MicroChemicals GmbH, Ulm, Germany) was spin coated onto the wafers to a thickness of approximately 6 m and then baked for 2 minutes at 90° C. The wafers were subsequently allowed to cool for at least 10 minutes before exposure.

The resist was exposed to a constant UV dose of 150 mJ/cm² and then developed in a mixture of 4:1 H₂O:AK400 (photoresist developer; MicroChemicals GmbH, Ulm, Germany) to completion. After rinsing, the wafers were immediately dried and loaded into an evaporation chamber. After reaching a base pressure of less than 10⁻⁶ Torr, sequential layers of chromium and gold were deposited with thicknesses of 5 and 175 nm respectively. After metallisation, the wafers were sonicated in acetone to lift off the photoresist, typically requiring approximately 20 mins for full lift-off from the substrate. Subsequently, the wafers were rinsed with acetone and further sonicated in successive baths of acetone and isopropanol for 5 mins. The wafers were then dried with nitrogen, coated with a protective layer of photoresist and diced into 3 cm×1 cm chips. After dicing, the chips were again cleaned with acetone and isopropanol and dried with nitrogen. The electrode fingers and the central working area of each chip were then coated with a 1 m layer of silicon dioxide using plasma enhanced chemical vapor deposition (Plasmalab System 100, Oxford Instruments, Abingdon, UK).

The reaction chamber housings 15 were cast in polydimethylsiloxane (PDMS; Sigma-Aldrich Pty. Ltd., Castle Hill, NSW, Australia) on masters that were fabricated using a 3D printer (Objet Eden 260V; Stratasys Ltd., Rehovot, Israel). The master consisted of a reaction chamber with a diameter of 8 mm, a height of 2 mm and an approximate volume of 100 L. The master also had 3 posts with a diameter of 0.5 mm and a height of 2 mm for the inlet and outlet ports. Three pieces of thin silicone tubing (0.02″ ID, 0.05″ OD; Gecko Optical, Joondalup, WA, Australia) were cut to a length of 4 mm and placed on the small posts as fixed inlets and outlet before casting the PDMS (FIG. 2). The masters were then placed in a disposable petri dish and the PDMS, prepared by mixing prepolymer and curing agent in a 10:1 ratio and degassed using a vacuum dessicator, was poured on top to a thickness of approximately 4 mm. The PDMS was then baked at 65° C. for two hrs. Prior to bonding with the PDMS, the lithium niobate substrates were rinsed with acetone and isopropanol, dried with nitrogen and subsequently exposed to air plasma at a pressure of 400 mTorr for 90 s in a plasma cleaner (Harrick Plasma, Ithaca, N.Y.). Immediately after plasma treatment, the PDMS chamber housings 15 were pressed into contact with the lithium niobate substrate and then heated in an oven at 60° C. for 1 hr to ensure permanent and even bonding. Unless otherwise stated, the inlet and outlet ports 11,12,0 are oriented with respect to the IDT 17 as shown in FIG. 2.

The SAW propagation direction is indicated in FIG. 2 by the bold arrow 18; as the SAW comes into contact with the liquid in the reaction chamber 19, it leaks its energy into the liquid to drive strong chaotic liquid recirculation (i.e., acoustic streaming) within the reaction chamber 19 in order to enhance the mixing within it.

### Device Setup and Characterisation

The SAW devices 5 were mounted on a custom-made jig that allowed the device to be connected to a signal generator (N9310, Agilent Technologies Pty. Ltd., Mulgrave, VIC, Australia) and amplifier (ZHL-5W-1, Mini-Circuits, Brooklyn, N.Y., USA). The operating frequency of the SAW device 5 was consistently determined to be 19.6 and 21.5 MHz verified for each device on an impedance analyser (4194A; Agilent Technologies Pty. Ltd., Mulgrave, VIC, Australia). The vibration surface displacement of the device 5 was determined using a high frequency laser Doppler vibrometer (UHF-120-SV; Polytec GmBH, Waldbronn, Germany). All images were taken through the optically transparent, double sided polished lithium niobate substrate.

Samples and reagents were injected into the reaction chamber 19 using syringe pumps 27A,29A (SP100i, World Precision Instruments Inc., Sarasota, Fla., USA) although the Applicant also verified and demonstrated the possibility for the use of portable micropumps (M200-P4; RS Compoments Pty. Ltd., Wetherill Park, NSW, Australia) for the purposes of complete integration and miniaturisability of the system, as shown in FIG. 1. Syringes were capped with 32 gauge needles (Livingstone International Pty., Rosebery, NSW, Australia) threaded onto approximately 50 cm of flexible PVC tubing (0.04″ ID, 0.08″ OD; Ormantine Ltd., Palm Bay, Fla., USA) and microbore PTFE tubing (0.012″ ID, 0.030″ OD; Cole-Parmer Instrument Co., Vernon Hills, Ill., USA), which was subsequently mounted manually onto the input ports 11,12 of the reaction chamber 19. The same tubing was also mounted on the outlet end and the waste was dispensed into an amber reagent bottle wrapped in aluminium foil to insulate the detection from any stray chemiluminescent signal arising from further reaction in the waste line. The device was filled with isopropanol and rinsed with water in order to remove air bubbles before operation.

### Micromixing Quantification

In order to investigate the effect as well as to optimise the mixing of the chemiluminescent reaction in the continuous flow system, mixtures of 1 mM fluorescein (analytical grade, Sigma-Aldrich Pty. Ltd., Castle Hill, NSW, Australia) and deionised water were initially used. Video images that captured the mixing were then acquired at 50 fps with a high-speed camera (FASTCAM SA-5; Photron Ltd., Tokyo, Japan) ported to an inverted microscope (Eclipse Ti-S, Nikon Instruments Inc., Tokyo, Japan) with a FITC filter set (Chroma Technology Corp., Bellows Falls, Vt., USA). A 2× objective was used to facilitate full view of the reaction chamber. Images were then cropped to exclude the exterior of the chamber for the purposes of determining the extent of mixing of the reaction in the chamber in each still frame of the video, which is quantified by a mixing index that is defined as

$$Mixing Index = \frac{S}{A} , \qquad ( 1 )$$

wherein S is the image standard deviation and A the average image intensity. The mixing index was normalised for all SAW experiments such that a mixing index value of unity represents the mixing in the absence of the SAW and a value of zero represents the fully mixed case. Given that the instantaneous normalised mixing indices for each frame stabilised after approximately 20 s, a representative steady-state mixing index for a given parameter set can then be calculated by averaging the instantaneous normalised mixing index over a period ranging from 28 to 30 s.

### Chemiluminescent Detection

Initial qualitative chemiluminescent experiments were performed in a darkroom box and recorded with a high resolution camera (EOS 550D SL; Canon Inc., Tokyo, Japan) with a macro lens (EF-S, 60 mm focal length, F2/8; Canon Inc., Tokyo, Japan). The camera was oriented to view the inside of the PDMS reaction chamber from beneath through the transparent lithium niobate substrate. Briefly, 2 mg/L L-proline in pH 9.0 sodium tetraborate buffer was mixed with 0.1 mM [Ru(bipy)₃]³⁺ in 200.0 mM sulphuric acid, whose reaction was given at least 5 mins to equilibrate prior to recording for any given flow rate. Once steady-state was reached, a series of images were taken in the darkroom box with an exposure time of 3.2 s keeping the camera setting the same. In order to compare the results of various experiments across a parameter set that allowed a range of flow rates and SAW power inputs to be investigated, the average mixing intensities of the reaction chamber were calculated and normalised against the steady-state mixing intensity in the absence of the SAW input.

Quantitative chemiluminescent detection experiments were carried out by continuously mixing each L-proline standard prepared in 50.0 mM sodium tetraborate buffer at pH 9.0 with the oxidised [Ru(bipy)₃]³⁺ reagent in the interior of the reaction chamber 19 at an optimal combined flow rate of 0.3 mL/min. LabVIEW (National Instruments Corp., Austin, Tex., USA) was used to power one set of IDTs by remotely triggering the signal generator to produce a pair of oppositely directed SAWs at a continuous surface displacement of approximately 1.2 nm. It is also possible to have a second IDT 17 to the piezoelectric 9 substrate on the opposite side of the reaction chamber 19. This arrangement, as well as allowing SAW to be generated from both sides of the reaction chamber 19, also facilitates the generation of a travelling SAW to be applied. The light signal produced by the chemiluminescent reaction was detected using a photomultiplier-tube (PMT) 16 (H10721-20; Hamamatsu Photonics K.K., Hamamatsu City, Japan). The photodetector cell of the PMT 16 was aligned with the reaction chamber 19 (both 8.0 mm in diameter) and the light captured through the lithium niobate wafer 9 at a distance <1 mm; both the reaction chamber 19 and the PMT were isolated in a dark instrument case (ABS Instrument Case with Purge Valve MPV4, Jaycar, Rydalmere, NSW, Australia). The PMT was connected to a data acquisition assistant (NI-USB 6008; National Instruments Corp., Austin, Tex., USA) and the data was logged using LabVIEW, which plotted the PMT response (V) against the analysis time (s) as well as the integrated area under each peak (Vs). The chemiluminescent response for each standard was recorded in the form of a baseline acquired over 60 s with the SAW device switched off, followed by a 10 s detection peak obtained with the SAW device switched on. Each standard was analysed in quintuplicate and a calibration curve was produced for a set of L-proline standards ranging from 0-0.5 ppb.

### Results and Discussion

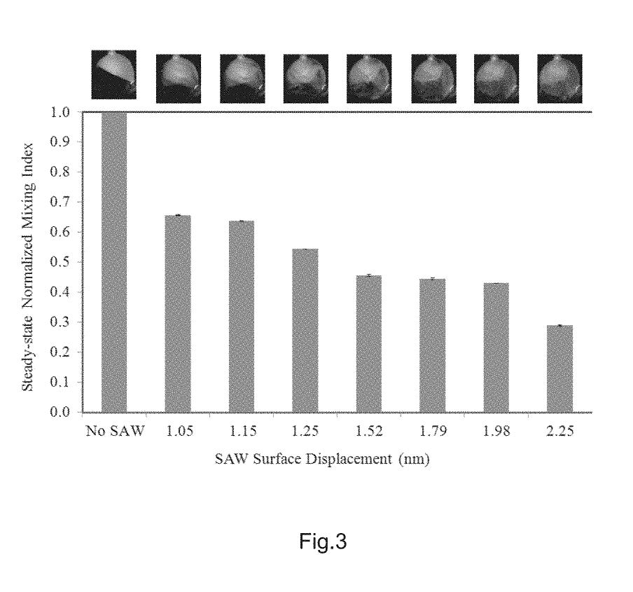

FIG. 3 is a graph showing effect of the SAW surface displacement (which is a function of the SAW input power) on the steady-state normalised mixing index . It can be seen that the mixing is enhanced, reflected by the decrease in the mixing index towards the fully-mixed state represented by a null value of the index, with higher surface displacement, i.e. , higher power. Also shown above are still images of the reaction chamber captured when at steady-state, showing the mixing (or lack thereof) in the chamber.

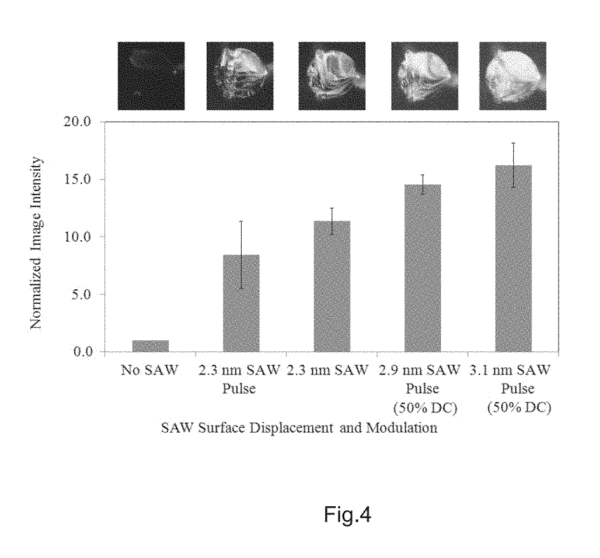

To enhance the micromixing and hence optimise the chemiluminescent detection, several different parameters were adjusted to investigate their effects on the mixing in the reaction chamber. We first observe in FIG. 3 that the mixing considerably improves when driven actively with the SAW and that the mixing intensity progressively increases with increasing SAW surface displacement (synonymous with the level of the SAW input power) as seen from the decreasing mixing index. This is due to the leakage of the SAW energy into the liquid in the reaction chamber 19 when the SAW comes into contact with the liquid, giving rise to strong liquid recirculation (i.e., acoustic streaming) and hence chaotic convection within the reaction chamber 19 such that the laminarity of the flow is disrupted which leads to a reduction in the diffusion length and time scales, thus resulting in an enhancement in the mixing. Nevertheless, the Applicant notes that there is a limit to which the SAW surface displacement can be increased, since high input powers beyond 5 W corresponding to a surface displacement amplitude >3.1 nm causes either boiling within the chamber and/or device fracture. To circumvent this limitation, it is possible to cycle the input signal to the SAW device 5 on and off rapidly over a pulse period of 500 ms and a pulse width of 250 ms with duty cycles of 25%, 50% and 75%. Using a 50% duty cycle allowed for surface displacements of up to 3.1 nm to be used without adversely affecting the device and further enhancing the mixing, as shown in FIG. 4. FIG. 4 is a graph showing the normalised average pixel intensity for images of the reaction chamber 19 (shown on top) at steady-state as a function of the SAW amplitude and modulation (pulsed operation with 50% duty cycle (DC). Error bars indicate 95% confidence intervals. In addition to improving the mixing efficiency, which can be attributed to intermittency effects which cause further disruption to the flow laminarity, using pulsed in place of the continuous operation has the advantage of reducing power consumption, thus facilitating further possible miniaturisation providing the power can be sufficiently reduced such that smaller batteries can be employed.

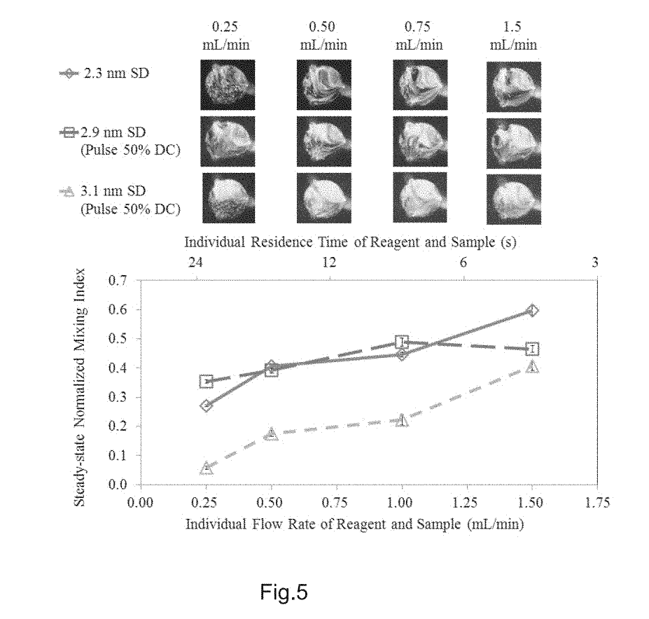

Nevertheless, unlike the case of batch SAW mixing in sessile drops or closed chambers that have been previously studied, there is an additional parameter that has a significant effect on the mixing of the sample and reagent in the system in continuous flow devices, namely the liquid flow rate and thus the liquid residence time within the chamber. This effect is shown in FIG. 5 wherein it can be generally observed that for a given SAW surface displacement, increases in the sample and reagent volumetric flow rate to the SAW device 5 causes an increase in the mixing index and hence a deterioration in the mixing intensity. FIG. 5 is a graphing showing steady-state normalised mixing index as a function of the volumetric flow rate through the reaction chamber and hence the liquid residence time in the chamber for different SAW surface displacement amplitudes, both in continuous and pulsed (50% duty cycle (DC)) modes. Corresponding images of the mixing in the reaction chamber 19 are shown above. Error bars represent 95% confidence intervals and the trendlines where added for ease of visualisation. This is because of the decrease in residence time in the reaction chamber 19, i.e., the duration over which the sample and reagent are exposed to the SAW before they leave the chamber. As such, an increase in the SAW input power is required to maintain the same mixing intensity if the flow rate is increased. Consistent with the results in FIG. 4, the mixing can be further enhanced for a given flow rate and SAW input power by utilising the pulsed SAW drive (here, the pulse duty cycle is kept constant at 50%) in place of continuous SAW excitation.

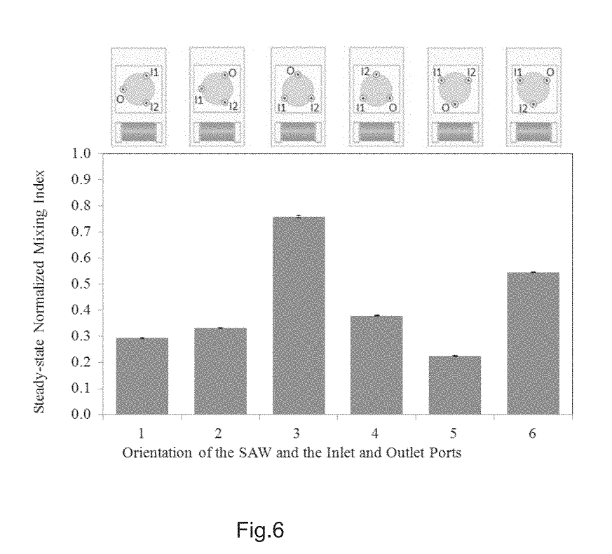

Longer residence times, equating to longer exposure to the SAW, for a fixed volumetric flow rate can also be achieved by varying the orientation of the reaction chamber 19 (i.e., the position of the inlet and outlet ports) with respect to the IDT 17 and hence the SAW propagation direction 18, as shown in FIG. 6. FIG. 6 is a graph showing the steady-state normalised mixing index for the different chamber orientations, ie , the position of the inlet (11 and 12) and outlet (0) ports relative to the IDT and hence the SAW propagation direction. The orientations are schematically depicted above. Error bars indicate 95% confidence intervals. It can clearly be seen that more efficient mixing can be obtained when the flow direction is perpendicular to that of the SAW propagation such that the SAW is most efficient in breaking the laminarity of the flow stream from the inlet to the outlet by inducing chaotic convection; similar enhancements in mixing have been reported, for example, when electric fields were applied perpendicular to the laminar flow direction and hence the interface between the streams to be mixed. Nevertheless, we note that the mixing can be further improved, however, by orienting the flow direction counter to that of the SAW propagation (i.e., configuration 5), for example, by positioning the inlet ports 11,12 on the far side directly opposite the IDT 17 and the outlet port 0 on the near side of the IDT 17. This observation confirms that the mixing enhancement in the system 1 is not solely due to the introduction of chaotic convection to disrupt the laminarity of the flow but also due to the increased residence time of the liquid in the reaction chamber 19 and hence the time over which the liquid is exposed to the SAW irradiation.

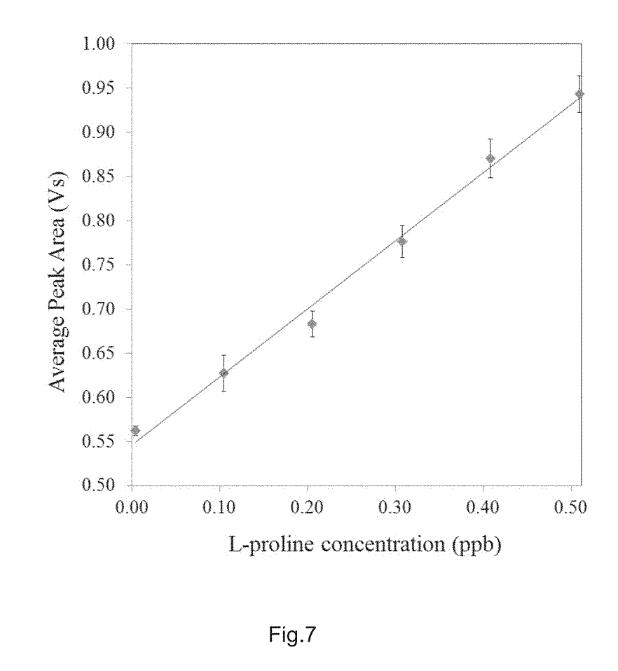

FIG. 7 shows the detection of proline with [Ru(bipy)₃]³⁺ using the photomultiplier-tube (PMT) 16 that was integrated into the chip-scale platform for the concentrations analysed, i.e., 0-0.5 ppb. In particular, FIG. 7 shows detection of proline using the PMT 16 integrated into the FIA system 1 in the presence of SAW micromixing (1.2 nm surface displacement and a combined flow rate of 0.3 mL/min), showing a marked increase in the detection sensitivity with the SAW mixing. The slope was obtained by linear regression with R²=0.82. Error bars indicate experimental standard deviation of the mean. We note that the chemiluminescent signal produced by the mixing inside the reaction chamber 19 varies randomly about a mean intensity. For such processes, the limit of detection can be calculated as three times the experimental standard deviation of the mean of the blank readings ,divided by the slope of the calibration curve , i.e., LOD=3/. From this calculation, we estimate the Limit of Detection (LOD) for L-proline to be 0.02 ppb with active micromixing driven by the SAW, thus achieving a detection limit that is two orders of magnitude more sensitive than that obtained with conventional benchscale FIA instrumentation for the same reaction and an order of magnitude more sensitive than the industry gold standard value for the detection of water pollutants naturally found at sub-ppb levels in source waters.

### CONCLUSIONS

The present invention preferably provides a continuous flow system 1 which integrates a miniaturised photodetection scheme that constitutes a portable and lightweight microfluidic flow injection analysis platform for the quantification of chemiluminescent species in liquid phase samples. Coupling acoustic energy into the liquid flowing through a microfabricated reaction chamber housing 15 cast in PDMS having a reaction chamber 19 and bonded onto the SAW actuator 6 drives strong and chaotic acoustic streaming that disrupts the laminarity of the flow, significantly enhancing the mixing within the reaction chamber 19 and thus allowing rapid in-line detection of the chemiluminescent signal emitted by the reaction.

In particular, the Applicant demonstrates that it is possible to achieve a hundredfold improvement in the detection limit to ng/L or parts per trillion sensitivity with the device compared to the limits of detection reported for conventional flow injection analysis systems, but without necessitating sample preconcentration, a severe limitation that has hampered other attempts to miniaturise other flow injection systems. The low cost and small size of the system further facilitates high throughput operation through scale out (i.e., numbering up as opposed to scaling up) of the system via the adoption of a large number of devices in parallel; a significant advantage of such scaling out is the ease in replacing a single device in the event of a fault or when maintenance is required without necessitating complete shutdown of an entire operation. This on-chip microfluidic mixing strategy, together with the integrated miniature photodetector and chip-scale microfluidic actuation using the same SAW setup, then suggests that a completely miniaturised low cost and lightweight platform that is sufficiently sensitive as a portable field-use micro-analytical system is within reach.

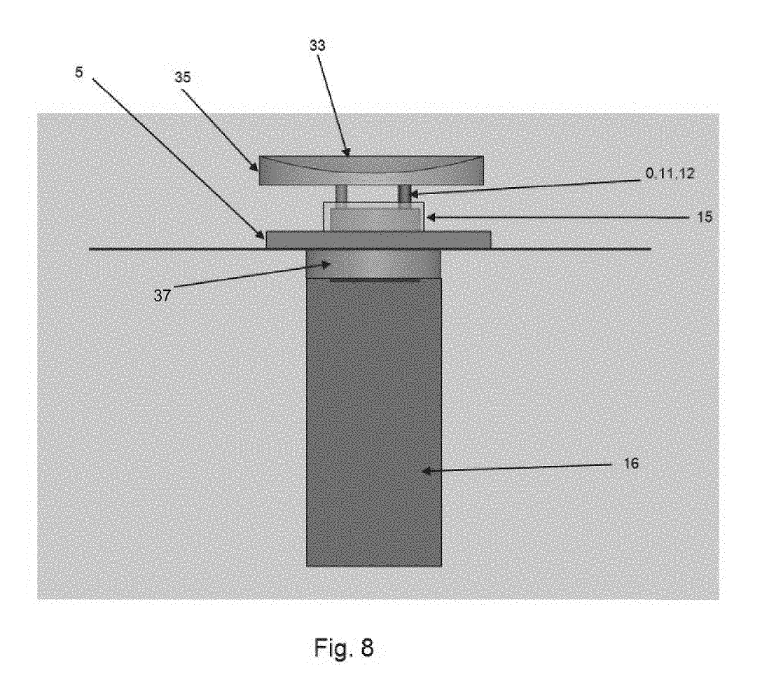

The chemical analysis system according to the present invention can also be adapted for use in the detection of fluorescent or phosphorescent emissions. FIG. 8 shows the chemical analysis system 1 according to the present invention adapted for fluorescent, luminescent or phosphorescent analysis. The detection of fluorescent or phosphorescent species using this system 1 can be made possible through the incorporation of an excitation source 33, an excitation filter 35 (facultive) and an emission filter 37 as shown in FIG. 8. An excitation source 33 or light source is necessary to provide light of intense, near-monochromatic wavelength to excite the fluorescent and/or phosphorescent species prior to detection. Suitable excitation sources 33 for this platform include xenon arc and mercury-vapour lamps, high power light-emitting diodes (LEDs) and lasers. Different fluorescent and phosphorescent samples have different excitation and emission wavelengths depending on their structure and composition. Hence, an excitation source 33 that emits a wide range of wavelengths may be used to detect a wide range of fluorescent and phosphorescent species if fitted with filters 35,37 of specific excitation and emission wavelengths. Excitation and emission filters consist of optical filters (glass or gelatin) which allow light of a specific wavelength to pass through to and from the sample. These include (short or long/narrow or broad) band pass filters, sharpcut filters, neutral density filters, monochromators, and wedge prisms coupled with narrow slits or holographic diffraction gratings. In this platform, the excitation filters 35 can be placed anywhere between the excitation source 33 and the sample. The emission filters 37 can be place anywhere between the sample and the photodetector 16. Both the excitation and the emission filters 35, 37 can be incorporated in any optimal configuration, including the use of optical fibre and a dichroic beam splitter cube.

Modifications and variations as would be deemed obvious to the person skilled in the art are included within the ambit of the present invention as claimed in the appended claims.

1. A chemical, biochemical or biological analysis system including:
a surface acoustic wave (SAW) actuator including a piezoelectric substrate and at least one interdigital electrode located on a working surface of the piezoelectric substrate, the SAW actuator generating travelling SAWs in the working surface when an electrical signal is applied to the interdigital electrode;
at least one reaction chamber located on the working surface of the piezoelectric substrate;
a light detector for detecting luminescent, fluorescent or phosphorescent emissions within the reaction chamber;
a reagent flow line for providing a flow of reagent through the reaction chamber;
a test sample supply line for supplying a test sample to the reaction chamber;
wherein the SAW actuator can generate travelling SAWs within the working surface to thereby induce chaotic micromixing, convective transport, concentration or combinations thereof of the test sample and the reagent contained within the reaction chamber.

2. A chemical, biochemical or biological analysis system according to claim 1, wherein the reaction chamber has a substantially circular cross-section.

3. A chemical, biochemical or biological analysis system according to claim 1, the system being a flow reaction analysis (FIA) system wherein the reagent flow line includes a reagent injector for injecting a continuous flow of the reagent to the reaction chamber, and the test sample flow line includes a test sample injector for injecting a batch of test sample into the reaction chamber.

4. A chemical, biochemical or biological analysis system according to claim 1, wherein the reaction chamber includes a reagent inlet port in communication with the reagent flow line, a sample inlet port in communication with the sample flow line, and an outlet port for the fluid contained within the reaction chamber.

5. A chemical, biochemical or biological analysis system according to claim 4, wherein the inlet ports and outlet port are positioned relative to each other such that a line passing through the outlet port and between the inlet ports is substantially aligned perpendicular to a general propagation direction of the SAW within the working surface.

6. A chemical, biochemical or biological analysis system according to claim 4, wherein the inlet ports and outlet ports are located relative to each other such that a line passing through the outlet port and between the inlet ports is substantially aligned with a general propagation direction of the SAW within the working surface, with the outlet port being located closest to the source of the SAW.

7. A chemical, biochemical or biological analysis system according to claim 1, wherein the light detector includes a photomultiplier tube having a photodetector cell for detecting the luminescent, fluorescent or phosphorescent emissions within the reaction chamber, the diameter of the reaction chamber being sized to substantially match the diameter of the photodetector cell, the photodetector cell being placed against a rear side of the piezoelectric substrate and aligned with the reaction chamber.

8. A chemical, biochemical or biological analysis system according to claim 7, further including excitation source located above the reaction chamber for exciting fluorescent and/or phosphorescent species within the reaction chamber prior to detection.

9. A chemical, biochemical or biological analysis system according to claim 8, further including an emissions filter located between the piezoelectric substrate and the light detector.

10. A chemical, biochemical or biological analysis system according to claim 8, further including an excitation filter between the excitation source and the reaction chamber.

11. A chemical, biochemical or biological analysis system according to claim 1, wherein the SAW actuator is subjected to a pulsed said electrical signal.

12. A chemical analysis, biochemical or biological system according to claim 1, including two said interdigital electrodes located on opposing sides of the reaction chamber.

13. A chemical, biochemical or biological analysis method utilising luminescent, fluorescent or phosphorescent detection in a chemical analysis system according to any one of the preceding claims, the method including:
applying an electrical signal to the SAW actuator to generate travelling SAW in the working surface of the piezoelectric substrate;
providing a flow of reagent through the reaction chamber;
supplying a test sample to the reaction chamber, the generated travelling SAW inducing chaotic micromixing, convective transport, concentration or combinations thereof of the test sample and the reagent within the reaction chamber; and
detecting luminescent, fluorescent or phosphorescent emissions from the mixed test sample and reagent.

14. A chemical, biochemical or biological analysis method according to claim 13, including providing a continuous flow of reagent to the reaction chamber.

15. A chemical, biochemical or biological analysis method according to claim 13, including applying a pulsed electrical signal to the SAW actuator.
